(19) United States
(12) Patent Application Publication
(10) Pub. No.: US 2002/0081842 A1
(43) Pub. Date: Jun. 27, 2002

(54) Electroless metal liner formation methods

(76) Inventors: Carlos J. Sambucetti, Croton-on-Hudson, NY (US); Steven H. Boettcher, Fishkill, NY (US); Peter S. Locke, Hopewell Junction, NY (US); Judith M. Rubino, Ossining, NY (US); Soon-Cheon Seo, White Plains, NY (US)

Correspondence Address: Tiffany L Townsend Attorney, International Business Machines Corporation, 2070 Route 52, Hopewell Junction, NY, 12533, US

(21) Appl. No.: 09/549,907

(22) Filed: Apr. 14, 2000

(51) Int. Cl. H01L 21/44

(52) U.S. Cl. 438/678

(57) ABSTRACT

A semiconductor structure, having a semiconductor dielectric material having an opening. A first material lining the opening, the first material comprising MXY, where M is selected from the group consisting of cobalt and nickel, X is selected from the group consisting of tungsten and silicon and Y is selected from the group consisting of phosphorus and boron and a second material filling the lined dielectric material.

### TECHNICAL FIELD OF THE INVENTION

This invention pertains generally to the manufacture of a microelectronic component, such as a high density system of interconnecting integrated circuits, and more particularly to the creation of liners, seed layers and barriers for metal features in integrated circuits.

### BACKGROUND OF THE INVENTION

As device size and metallurgy change and shrink, the step coverage of the liner/seed layer at the sidewall and the bottom of a given level's lines and vias is becoming fraught with complications. With the current trends towards higher aspect ratios and smaller overall dimensions, current deposition methods and materials can produce liners and seed layers with less than complete coverage on all of the necessary sidewall surfaces. Where coverage is incomplete, the metal filling the lines and vias can seep into the dielectric material surrounding the lines/via, effectively “poisoning” the dielectric material adjacent to the incontinuity and electrical connection can be compromised.

Physical vapor deposition (PVD) and chemical vapor deposition (CVD) are currently popular methods for liner layer deposition. By liner layer it is meant the layers deposited on a patterned dielectric material on a semiconductor material after etching the openings that current level lines and vias will occupy. By feature it is meant a metal filled opening. User defined designs will control the placement of lines and vias. Liners and seed layers are often necessary for a number of reasons. With incomplete liner coverage the metal that will eventually fill the etched openings may diffuse into the dielectric material. This may eventually degrade the device performance. Also, the metal may not adhere to the dielectric material. In some cases, the liner may comprise more than one material or more than one phase of a single material. A seed layer may be necessary to ensure complete metal filling. The need for a seed layer is dependent on the deposition method. By liner/seed layer it is meant a single deposited layer that serves dual purposes. A liner/seed layer is a layer that prevents diffusion of the metal into the surrounding dielectric material, has good electrical conductivity and has good metal adherence properties.

Common liner materials for copper, aluminum and AlCu include tantalum, tungsten, titanium and compounds containing titanium tungsten and tantalum such as tantalum nitride and titanium nitride. Other liner materials for copper, aluminum, and AlCu include seed layer deposition of whichever metal is being used. Difficulties arise when the deposition method produces uneven results and there is not continuous coverage. Also, as dimensions shrink, it will be advantageous to minimize the thickness of all layers, even liner and liner/seed layers. It will also be advantageous to simplify the deposition processes as much as possible. If a single layer deposition can replace a 2-3 step liner and seed layer process it will lead to cost savings and increased efficiencies. Thus there remains a need for a material that can act as a liner and a liner/seed layer and provides a continuous interface between the metal and the dielectric material surrounding the opening.

### SUMMARY OF THE INVENTION

It is therefore an object of the invention to provide an improved structure which provides a single layer that has liner integrity and electrical continuity between the current level and other metal levels.

It is also an object of the instant invention to provide a structure having a novel liner material that provides continuity surface coverage at high aspect ratios and small dimensions.

In accordance with the above listed and other objects, the invention discloses and claims a microelectronic method, comprising a method of forming semiconductor features, comprising:

Plating an opening in a dielectric material with a first material, the material comprising CoXY, where X is selected from the group consisting of tungsten and silicon and Y is selected from the group consisting of phosphorus and boron.

Also in accordance with the above listed and other objects, the invention discloses and claims a microelectronic structure comprising a semiconductor dielectric material having an opening;

A first material lining the opening, the first material comprising MXY, where M is selected from the group consisting of cobalt and nickel, X is selected from the group consisting of tungsten and silicon and Y is selected from the group consisting of phosphorus and boron; and

A second material filling the lined dielectric material.

These and other objects, features, and advantages of the invention are evident from the following description of a preferred mode for carrying out this invention with reference to the accompanying drawing.

### BRIEF DESCRIPTION OF THE DRAWINGS

FIG. 1, which is not drawn to scale or to true proportions, is a fragmentary, cross sectional view of an intermediary step in the method of the instant invention.

FIG. 2, which is not drawn to scale or to true proportions is a fragmentary, cross-sectional view of one embodiment of the instant invention.

FIG. 3, which is not drawn to scale or to true proportions is a fragmentary, cross-sectional view of another embodiment of the instant invention.

### DESCRIPTION OF THE PREFERRED EMBODIMENTS

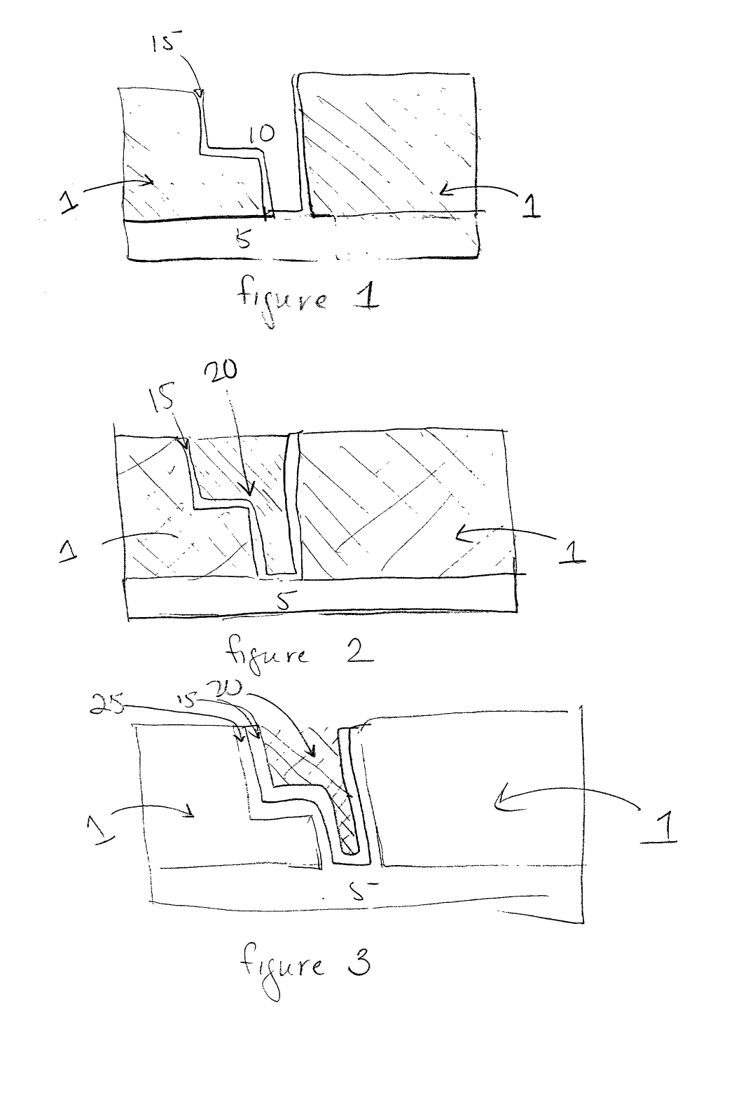

Being useful in the manufacture of a microelectronic component, such as a high density, integrated circuits having copper metallurgy and with reference to FIG. 1, this invention provides an improved method for providing a copper liner and a copper structure having novel liner. The structure shown in FIG. 1 shows a semiconductor dielectric material 1, with a current metal level line/via feature, 10, already etched by any means known in the art. The feature is lined with an electroless plated Co-W-P layer, 15.

Broadly, the improved method contemplates electroless plating of the metallic features with a Co—W—P (cobalt-tungsten-phosphorus) alloy forming a layer having a thickness in the range of about 50-500 Å (angstroms) deposited at a rate in a range from about 40 Å per minute to about 150 Å per minute, in an aqueous plating bath having a temperature preferably in a range from about 70 to about 80° C. and a pH in a range from about 8 to about 9. The aqueous plating bath comprises low concentrations of cobalt and tungstate ions, a hypophosphite, buffering and complexing agents and a surfactant. The surfactant is present in a range from about 0.01 grams per liter to about 0.2 grams per liter, the hypophosphite in a range from about 5 grams per liter to about 15 grams per liter, the buffering agent in a range from about 10 grams per liter to about 30 grams per liter, the complexing agent in a range from about 15 grams per liter to about 50 grams per liter, the cobalt salt in a range from about 5 grams per liter to about 15 grams per liter and the tungstate salt in a range from about 1 gram per liter to about 10 grams per liter. Suitable reducing agents include hypophosphite and dimethylaminoborane. Suitable buffering agents include boric acid. Suitable complexing agents include's sodium citrate and suitable surfactants include potassium perfluoroalkyl sulfonate. Suitable tungstate salts include ammonium tungstate. Suitable cobalt salts include cobalt sulfate.

When the improved method is employed, a conformal liner layer and/or seed layer can be deposited. The method of the present invention provides an efficient barrier layer ire and a continuous conducting layer for complete hole fill performances.

In the aqueous plating bath used in the preferred mode for carrying out this invention, the cobalt salt is cobalt sulfate in the amount 8 grams per liter and the tungsten salt is ammonium tungstate in the amount of about 3 grams per liter. Acting as a reducing agent to covert cobalt to its elemental form, the hypophosphite is sodium hypophosphite in an amount of about 10 grams per liter. The buffering agent is boric acid in an amount of about 15 grams per liter. The complexing agent is sodium citrate in an amount of about 30 grams per liter. It is important to use buffering and complexing agents which do not leave deleterious byproducts. As the surfactant, Fluorad™ FC-98 surfactant (potassium perfluoroalkyl sulfonate) which is commercially available from Minnesota Mining and Manufacturing Company, Industrial Chemical Products Division, St. Paul Minn., in an amount of about 0.1 grams per liter is suitable. Other surfactants may be alternatively useful. The aqueous plating path has a temperature of about 72° C. and a pH of about 8.1.

When the etched lines/vias present in the semiconductor dielectric material are subjected to electroless plating in the aqueous plating bath described in the preceding paragraph, the layer of Co—W—P alloy, 15, is deposited on the dielectric material, 1, so as to reach a thickness in the range from about 50 Å to about 500 Å at a rate of about 50 Å per minute. After the layer, 15, reaches such a thickness, the dielectric material, 1, with the plated liner, 15, on the etched features, 10, is removed from the aqueous plating bath and is rinsed.

FIG. 2 shows the final metal filled structure obtained by the example shown previously. Metallic features, 20, are formed on a previously deposited layer, 5, that may or may not contain metallic features in electrical contact with the current level being processed. The features, 20, are disposed on a nonmetallic or semiconductive material, 1. A liner layer, 15, is deposited between the metal of the metallic layer, 20, and the dielectric material. In this embodiment the electroless plated Co—W—P layer acts as the liner layer for the metallic feature. In this embodiment where the metal is copper, the Co—W—P layer also acts as the seed layer. In a preferred embodiment the Co—W—P layer would be about 150-300 Å thick.

FIG. 3 shows an alternative structure using the instant invention. In FIG. 3, prior to the electroless plating of Co—W—P, 15, a liner layer, 25, is deposited. The liner layer, 25, can be of any composition compatible with the substrates and metals that are in contact with the liner. For example, where the underlying layer, 5, is metal and the metal on the current level, 20, are both copper a liner layer of a combination of Ta and TaN can be deposited. The electroless deposition of Co—W—P would then proceed as previously described. Co—W—P is useful as dimensions of features shrink. It is increasingly more difficult to fully cover all the sidewalls of a line/via with current techniques and materials and electroless plated Co—W—P provides an alternative which forms continuous seed layers and liners.

The same materials can be used for either of the structures shown in FIGS. 2 and 3. The liner/seed material of the instant invention is not limited to Co—W—P. Examples of preferred materials that could be used as the liner/seed layer include thin film alloys of elements such as cobalt, nickel, tungsten, silicon, tin, phosphorous and boron and in general materials which form alloys of the form Co—X—Y where X is a secondary component such as W, Sn or Si and Y is phosphorous or boron, for example CoWB, CoSiP, CoSnP, CoSnB and CoSiB. Other alloys having similar results include NiWP, NiSiP, NiSiB, NiWB, NiSnP and NiSnB.

While the invention has been described in detail herein in accordance with certain preferred embodiments hereof, many modifications and changes therein may be effected by those skilled in the art. Accordingly, it is intended by the appended claims to cover all such modifications and changes as fall within the true spirit and scope of the invention.

What is claimed:

1. A method of forming semiconductor features, comprising:
Plating an opening in a dielectric material with a first material, the material comprising coxy, where X is selected from the group consisting of tungsten, tin and silicon and Y is selected from the group consisting of phosphorus and boron.

2. The method according to claim 1 wherein the plating is electroless plating.

3. The method according to claim 1 wherein the first material is adjacent to the dielectric material.

4. The method according to claim 1 further comprising the step of depositing a second material prior to the plating step.

5. The method of claim 4 wherein the second material comprises a member selected from the group consisting of tantalum, titanium, tungsten, tungsten nitride, tantalum nitride and titanium nitride.

6. The method according to claim 1 wherein the thickness of the first material is about 50 Å to about 500 Å.

7. The method according to claim 6 wherein the thickness of the first material is about 150 Å to about 300 Å.

8. A method of forming semiconductor features, comprising:
Plating an opening in a dielectric material with a first material, the material comprising NiXY, where X is selected from the group consisting of tungsten, tin and silicon and Y is selected from the group consisting of phosphorus and boron.

9. The method according to claim 8 wherein the plating is electroless plating.

10. The method according to claim 8 wherein the first material is adjacent to the dielectric material.

11. The method according to claim 8 further comprising the step of depositing a second material prior to the plating step.

12. The method of claim 11 wherein the second material comprises a member selected from the group consisting of tantalum, titanium, tungsten, tungsten nitride, tantalum nitride and titanium nitride.

13. The method according to claim 8 wherein the thickness of the first material is about 50 Å to about 500 Å.

14. The method according to claim 13 wherein the thickness of the first material is about 150 Å to about 300 Å.

15. A semiconductor structure, comprising:
A semiconductor dielectric material having an opening;
A first material lining the opening, the first material comprising MXY, where M is selected from the group consisting of cobalt and nickel, X is selected from the group consisting of tungsten, tin and silicon and Y is selected from the group consisting of phosphorus and boron; and
a second material filling the lined dielectric material.

16. The structure of claim 15 wherein the second material is a metal.

17. The structure of claim 16 wherein the second material is copper.

18. The structure of claim 15 wherein the first material is adjacent to the dielectric material and the second material is adjacent to the first material.

19. The structure of claim 15 further comprising a third material the third material disposed between the di electric material and the first material.

20. The structure according to claim 19 wherein the third material is adjacent to the dielectric material, the first material is adjacent to the third material and the second material is adjacent to the first material.

21. The structure according to claim 19 wherein the third material comprises a member selected from the group consisting of tantalum, titanium, tungsten, tungsten nitride, tantalum nitride and titanium nitride.
